(19) United States
(12) Patent Application Publication
(10) Pub. No.: US 2024/0404860 A1
(43) Pub. Date: Dec. 5, 2024

(54) PLASMA PROCESSING APPARATUS AND METHOD

(71) Applicant: Taiwan Semiconductor Manufacturing Company, Ltd., Hsinchu (TW)

(72) Inventors: Chun-Fu Kuo, Kaohsiung City (TW); Bing-Hung Chen, Taipei (TW); Li-Te Lin, Hsinchu (TW); Hao-Heng Liu, Hsinchu (TW)

(73) Assignee: Taiwan Semiconductor Manufacturing Company, Ltd., Hsinchu (TW)

(21) Appl. No.: 18/327,590

(22) Filed: Jun. 1, 2023

(51) Int. Cl. H01L 21/683; H01J 37/32

(52) U.S. Cl. CPC H01L 21/6833; H01J 37/32091; H01J 37/32174; H01J 37/32715; H01J 2237/332; H01J 2237/334

(57) ABSTRACT

Processing apparatuses and methods are provided. A processing apparatus includes an electrostatic chuck configured to hold a semiconductor wafer during a process performed on the semiconductor wafer; a first electrode configured to bias a first region of the electrostatic chuck with a first bias; and a second electrode configured to bias a second region of the electrostatic chuck with a second bias.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography and etching processes to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise within each of the processes that are used, and these additional problems should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a view of a plasma processing apparatus according to embodiments of the present disclosure.

FIG. 2 is a schematic cross-sectional view of the electrostatic chuck of the plasma processing apparatus of FIG. 1 according to embodiments of the present disclosure.

FIG. 3 is a schematic cross-sectional view of the electrostatic chuck taken along line 3-3 in FIG. 2, according to embodiments of the present disclosure.

FIGS. 4-7 are schematic cross-sectional views, similar to FIG. 3, of alternative embodiments of the electrostatic chuck, according to embodiments of the present disclosure.

FIG. 8 is a schematic of a power source of the plasma processing apparatus of FIG. 1 according to embodiments of the present disclosure.

FIG. 9 is a schematic of a power source of the plasma processing apparatus of FIG. 1 according to embodiments of the present disclosure.

FIG. 10 is a flow chart illustrating a method for plasma processing, according to embodiments of the present disclosure.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms such as “about” and “substantially,” and the like may be used herein for ease of description. A person having ordinary skill in the art will be able to understand and derive meanings for such terms. For example, “about” may indicate variation in a dimension of 20%, 10%, 5%, or the like, but other values may be used when appropriate. A large feature, such as the longest dimension of a semiconductor fin may have variation less than 5%, whereas a very small feature, such as thickness of an interfacial layer may have variation of as much as 50%, and both types of variation may be represented by the term “about.” “Substantially” is generally more stringent than “about,” such that variation of 10%, 5% or less may be appropriate, without limit thereto. A feature that is “substantially planar” may have variation from a straight line that is within 10% or less. A material with a “substantially constant concentration” may have variation of concentration along one or more dimensions that is within 5% or less. Again, a person having ordinary skill in the art will be able to understand and derive appropriate meanings for such terms based on knowledge of the industry, current fabrication techniques, and the like.

In certain embodiments herein, a “material layer” is a layer that includes at least 50 wt. % of the identified material, for example at least 60 wt. % of the identified material, at least 75 wt. % of the identified material, or at least 90 wt. % of the identified material, or substantially 100 wt. % of the identified material; and a layer that is a “material” includes at least 50 wt. % of the identified material, for example at least 60 wt. % of the identified material, at least 75 wt. % of the identified material, or at least 90 wt. % of the identified material, or substantially 100 wt. % of the identified material. For example, certain embodiments, each of a titanium nitride layer and a layer that is titanium nitride is a layer that is at least 50 wt. %, at least 60 wt. %, at least 75 wt. %, titanium nitride, or at least 90 wt. %, or substantially 100 wt. %, titanium nitride.

Semiconductor fabrication generally involves the formation of electronic circuits by performing multiple depositions, etchings, annealing processes, and/or implantations of material layers, whereby a stack structure including many semiconductor devices and interconnects between is formed. Dimension scaling (down) is one technique employed to fit ever greater numbers of semiconductor devices in the same area. However, dimension scaling is increasingly difficult in advanced technology nodes.

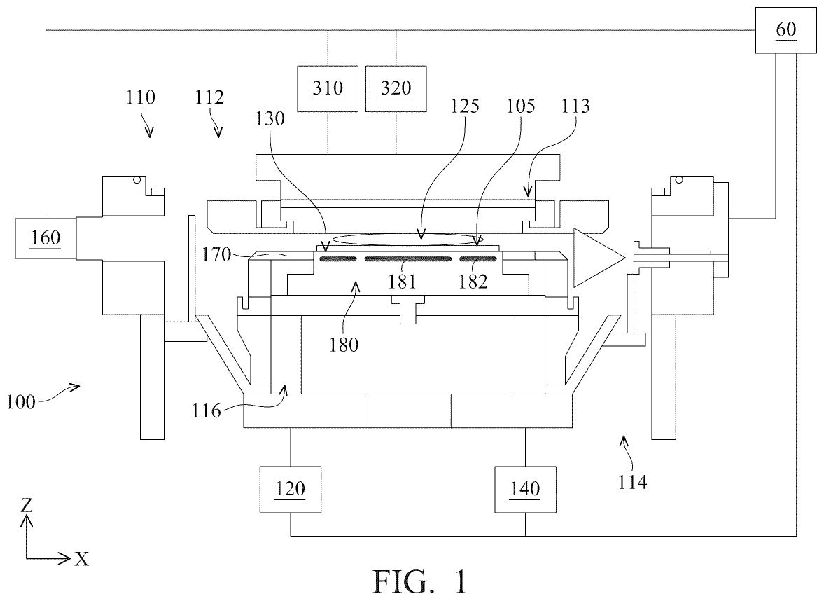

FIG. 1 is a schematic view of a plasma processing apparatus 100, according to various embodiments of the disclosure. In some embodiments, the semiconductor processing apparatus 100 is configured for performing etching, deposition, or other suitable process. In some embodiments, the semiconductor processing apparatus 100 is any plasma etching or dry etching tool that produces a plasma from a process gas, typically oxygen, chlorine-bearing gas, or fluorine-bearing gas, and uses a radio frequency (RF) electric field. In some embodiments, the semiconductor processing apparatus 100 is an ion-beam etcher, reactive ion etcher, or the like. In other embodiments, instead of an etching apparatus, the semiconductor processing apparatus 100 is a plasma deposition apparatus, such as a plasma-enhanced atomic layer deposition (PEALD) apparatus or the like.

In some embodiments, the plasma processing apparatus 100 may be Capacitively Coupled Plasma (CCP) apparatus. A CCP plasma source uses a pair of electrodes to create a plasma. The electrodes are separated by a small gap, and an AC voltage is applied between them. The voltage creates an electric field that ionizes gas and creates a plasma between the electrodes. CCP is a commonly used plasma source in semiconductor manufacturing and other plasma processing applications.

In other embodiments, the plasma processing apparatus 100 may be an Electron Cyclotron Resonance (ECR) apparatus that uses a high-frequency electromagnetic field to ionize gas and create a plasma. In such an apparatus, the electromagnetic field is created by injecting microwaves into a chamber containing a magnetic field. The magnetic field traps electrons in a circular path, where they gain energy from the microwaves and collide with neutral gas molecules to create ions and free radicals.

In other embodiments, the plasma processing apparatus 100 may be an Inductively Coupled Plasma (ICP) apparatus. An ICP plasma source uses a coil to create a magnetic field that ionizes gas and creates a plasma. The coil is typically wrapped around a cylindrical chamber containing the gas to be ionized. An RF power source is applied to the coil, creating an electromagnetic field that ionizes gas and creates a plasma in the chamber. ICP is a highly efficient and flexible plasma source that can be used for a variety of plasma processing applications, including surface modification, thin-film deposition, and etching.

In other embodiments, the plasma processing apparatus 100 may be a physical vapor deposition (PVD) apparatus. In PVD, a material is vaporized from a solid source and deposited as a thin film on a substrate. Plasma can be used in PVD processes to ionize the vaporized material and enhance its reactivity, which can improve the film quality and properties. There are several types of PVD processes that use plasma, including sputtering and ion plating. In sputtering, plasma is used to eject atoms from a solid target material and deposit them on the substrate. In ion plating, a high-energy plasma is used to ionize the vaporized material and accelerate the ions onto the substrate.

Regardless of the specific apparatus and process, plasma etching apparatuses and plasma deposition apparatuses may be collectively referred to as plasma processing apparatuses for performing plasma processing.

Referring to FIG. 1, the apparatus 100 for plasma processing a workpiece such as a semiconductor wafer for fabrication of a semiconductor device is described in accordance with various embodiments. During a plasma process, an electrostatic chuck (ESC) may hold the semiconductor wafer in place by using an electrostatic force. Further, the electrostatic chuck applies a bias to the semiconductor wafer, which helps to control the ion energy and directionality during processing. By applying a bias to the wafer, the energy of the ions that are bombarding the wafer can be controlled. Thus, the etching or deposition rates, as well as the selectivity of the process can be controlled. The DC bias voltage applied to the electrostatic chuck may be from several hundred volts to several kilovolts.

In embodiments herein, the bias voltage applied to the wafer is a direct current (DC) signal. In some cases, the bias voltage may also be modulated to achieve specific process results. For example, the DC signal may be pulsed or formed with a waveform of any desired frequency. Pulsed DC bias involves the application of a series of short, high-voltage pulses to the electrostatic chuck. The pulses typically have a duration of a few microseconds to several milliseconds, and the repetition rate can be adjusted depending on the application. The amplitude and duration of the pulses can also be varied to achieve the desired bias voltage.

Further, in embodiments herein, different bias voltages/DC signals are applied to different regions of the electrostatic chuck and/or wafer. In some embodiments, each bias voltage/DC signal may be dynamically controlled.

For example, a first bias voltage/DC signal is applied to a first region of the electrostatic chuck and to a first zone of a wafer lying thereon, while a second bias voltage/DC signal is applied to a second region of the electrostatic chuck and second zone of the wafer lying thereon. Likewise, additional bias voltage/DC signals may be applied to additional regions of the electrostatic chuck and zones of the wafer, for any desired and suitable number of regions of the electrostatic chuck and zones of the wafer. As a result, different regions of the electrostatic chuck, and zones of the semiconductor wafer lying on the electrostatic chuck, may be dynamically provided with different desired biases.

Certain embodiments use multi-zone DC pulsing technology with local coupling to achieve better bias uniformity, and adjustable biasing during plasma processing. Such embodiments are applicable to any apparatus using bias voltage and/or plasma processing.

As shown in FIG. 1, the semiconductor processing apparatus 100 includes a process chamber 110, and a source of radio frequency (RF) power 120 configured to provide RF power in the process chamber 110. The semiconductor processing apparatus 100 also includes an electrostatic chuck 130 within the process chamber 110, and the electrostatic chuck 130 is configured to receive and secure a wafer 105. The semiconductor processing apparatus 100 also includes a chuck electrode or electrode arrangement 180, and a source of direct current (DC) power 140 connected to the chuck electrode arrangement 180 via a cable or interconnect. The source of DC power 140 is configured to provide power to the chuck electrode arrangement 180. The DC power source 140 is located outside of the chamber 110 where the plasma process takes place.

The semiconductor processing apparatus 100 also includes a gas source 310 configured to introduce process and/or carrier gases into the process chamber 110. The semiconductor processing apparatus 100 may further includes a flow verification unit 320 configured to measure and/or verify flow rate of the process and/or carrier gases into the process chamber 110.

In some embodiments, the wafer 105 includes a single crystalline semiconductor layer on at least its surface. In some embodiments, the wafer 105 includes a single crystalline semiconductor material such as, but not limited to Si, Ge, SiGe, GaAs, InSb, GaP, GaSb, InAlAs, InGaAs, GaSbP, GaAsSb, and InP. In some embodiments, the wafer 105 is made of Si. In some embodiments, the wafer 105 is a silicon wafer. In some embodiments, the wafer 105 is a semiconductor-on-insulator substrate fabricated using separation by implantation of oxygen (SIMOX), wafer bonding, and/or other suitable methods, such as a silicon-on-insulator (SOI) substrate, a silicon germanium-on-insulator (SGOI) substrate, or a germanium-on-insulator (GOI) substrate. In some embodiments, the wafer 105 is a Si wafer having a mirror polished surface on one side or both sides. In some embodiments, the wafer 105 includes one or more integrated circuit (IC) dies in an intermediate (unfinished) stage of fabrication, such that plasma etching or deposition is performed on at least a topmost layer of each of the IC dies by the semiconductor processing apparatus 100.

In some embodiments, the process chamber 110 includes an upper portion 112 and a lower portion 114, which may include at least one conductive material, such as aluminum, as well as other non-conductive or semiconductive materials. The upper portion 112 includes an upper electrode 113, in some embodiments. In some embodiments, the lower portion 114 includes an insulating ceramic frame 116 and includes the electrostatic chuck 130 within the insulating ceramic frame 116. For example, the electrostatic chuck 130 is disposed within the insulating ceramic frame 116 within the lower portion 114 of the process chamber 110, as shown in FIG. 1. In some embodiments, the electrostatic chuck 130 includes a conductive sheet, which serves as the chuck electrode arrangement 180. As shown in FIG. 1, the chuck electrode arrangement 180 is connected to the source of DC power 140. When a DC voltage from the source of DC power 140 is applied to the chuck electrode arrangement 180 of the electrostatic chuck 130 having the wafer 105 disposed thereon, a Coulomb force is generated between the wafer 105 and the chuck electrode arrangement 180. The Coulomb force attracts and holds the wafer 105 on the electrostatic chuck 130 until the application of the DC voltage from the source of DC power 140 is discontinued.

In some embodiments, in order to improve the heat transfer between the wafer 105 and the electrostatic chuck 130, one or more gases, such as He or Ar, is introduced between the wafer 105 and the electrostatic chuck 130 by the gas source 310. In some embodiments, the gas dissipates heat generated between the wafer 105 and the electrostatic chuck 130 during the application of the DC voltage.

As illustrated in FIG. 1, the semiconductor processing apparatus 100 also includes a pump 160 connected to the process chamber 110. The pump 160 is configured to provide a vacuum or maintain a certain gas pressure within the process chamber 110. In some embodiments, the pressure within the process chamber 110 is maintained by the combination of the gas or gases being introduced by the gas source 310 and a level of pumping performed by the pump 160. In some embodiments, the pressure within the process chamber 110 is maintained solely by pumping with the pump 160.

In some embodiments, the source of RF power 120 is turned on to apply a plasma 125 for plasma etching operations. The source of RF power 120 may be configured to generate an RF signal operating at a set frequency (e.g., 13.56 MHZ), which transfers energy from the source of RF power 120 to the gas within the processing chamber 110. When sufficient power has been delivered to the gas, a plasma is ignited. In some embodiments, the power applied during the etching operations ranges from about 200 watts to about 700 watts. In some embodiments, application of an RF pulse occurs for a duration of about 10 seconds to about 60 seconds.

In some embodiments, the semiconductor processing apparatus 100 further includes a focus ring 170. The focus ring 170 surrounds at least a portion of the electrostatic chuck 130 and/or the wafer 105 and may have a generally annular shape. The focus ring 170 may be made of a conductive material, a metal material, a semiconductor material, or another material. In some embodiments, the focus ring 170 may be made of doped or undoped silicon. In some embodiments, the focus ring 170 may be coupled to the source of DC power 140. For example, at least one DC voltage is applied to the focus ring 170 by the source of DC power 140, such that the focus ring 170 may be electrically biased by the DC power source 140 at a DC voltage during the etching process.

Operations of various components of the processing apparatus 100 may be controlled by a controller 60 connected to the components, for example, by one or more wired connections and/or wireless connections. The wired connections may be electrical, optical, or another suitable connection type. The wireless connections may be by electrical antennae, optical receivers, or other suitable wireless connection types. In some embodiments, the controller 60 is connected to one or more of the source of RF power 120, the source of DC power 140, the pump 160, the gas source 310 and the flow verification unit 320 for controlling operations thereof.

Although the semiconductor processing apparatus 100 may be described above as a capacitively coupled plasma generator, embodiments are not intended to be limited to a capacitively coupled plasma generator. Rather, any suitable method of generating the plasma, such as inductively coupled plasma systems, magnetically enhanced reactive ion etching, electron cyclotron resonance, a remote plasma generator, or the like, may be utilized. All such methods are fully intended to be included within the scope of the embodiments.

Although a number of particular parts of the semiconductor processing apparatus 100 have been described above, other suitable parts may also be included. For example, endpoint mounts, liners, and any other parts that may help operate or control the etching process may also be included. All such parts are fully intended to be included within the scope of the embodiments.

In FIG. 1, the chuck electrode arrangement 180 is formed as two separate electrodes 181 and 182. Each electrode 181 and 182 may be independently supplied with different bias voltages or DC signals. Such an arrangement 180 allows for locally controlling the bias across the electrostatic chuck 130, rather than having a single uniform bias applied to the whole electrostatic chuck.

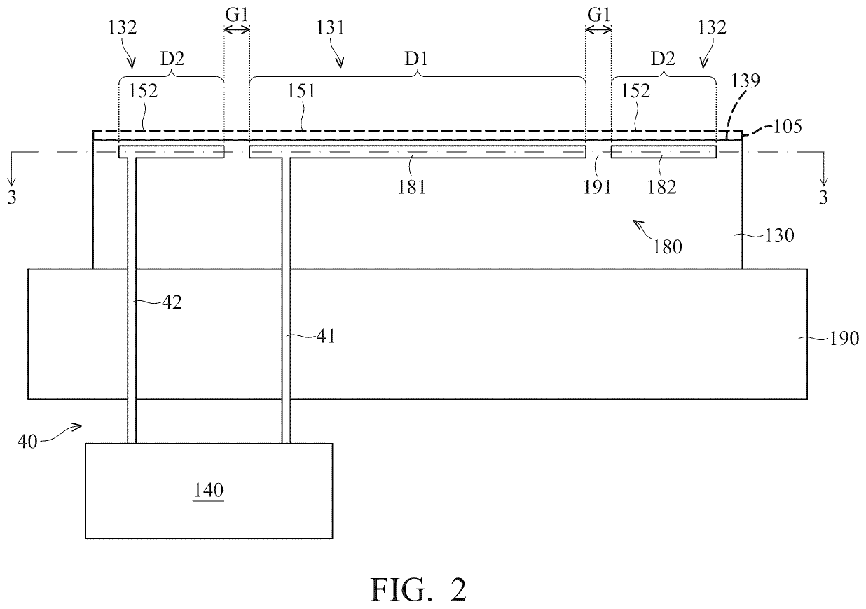

In FIG. 2, the electrostatic chuck 130 and chuck electrode arrangement 180 are illustrated more clearly. As shown, the electrostatic chuck 130 is located on a base plate 190. Further, the chuck electrode arrangement 180 is connected to the DC power source 140 by a cable or interconnect 40. As shown, the cable 40 may be routed through the base plate 190 or other components of the plasma processing equipment.

Electrostatic chuck 130 is configured to hold and immobilize a silicon wafer or other substrate on its upper surface 139 during plasma processing. The electrostatic chuck 130 works by creating an electrostatic force between the electrode arrangement 180 and the wafer, which holds the wafer in place. The electric field also controls or modifies movement of the ions in the plasma to bombard the wafer, enabling various plasma processes such as etching, deposition, and cleaning to take place. The electrostatic chuck 130 may be made of various materials, including ceramics, metals, and plastics.

As shown, electrode 181 is located at a central position. Electrode 181 may be generally a disk-shaped sheet and have a diameter D1. Electrode 181 may be coupled to the DC power source 140 by a first cable or interconnect 41. As shown, electrode 182 is located radially outward from electrode 181. Electrode 182 may be generally annular shaped sheet and have a radial width or distance D2. Electrode 182 may be coupled to the DC power source 140 by a second cable or interconnect 42.

As shown, electrode 181 is distanced from electrode 182 by a gap 191. Gap 191 is generally annular has a radial width or distance G1 in directions perpendicular to the Z-axis. Thus, electrode 181 is distanced from electrode 182 by radial distance G1. Radial distance G1 may be any suitable distance, such as at least 1 millimeter (mm), at least 2 mm, at least 3 mm, at least 4 mm, at least 5 mm, at least 6 mm, at least 7 mm, at least 8 mm, at least 9 mm, at least 10 mm, at least 15 mm, at least 20 mm, or at least 30 mm; and at most 2 mm, at most 3 mm, at most 4 mm, at most 5 mm, at most 6 mm, at most 7 mm, at most 8 mm, at most 9 mm, at most 10 mm, at most 15 mm, at most 20 mm, or at most 30 mm.

A first region 131 of the surface 139 of the electrostatic chuck 130 lies directly over the first electrode 181 in the Z-direction, i.e., the first region 131 lies vertically over the first electrode 181. Thus, the first region 131 is generally a circular area and has a diameter D1. A second region 132 of the surface 139 of the electrostatic chuck 130 lies directly over the second electrode 182 in the Z-direction, i.e., the second region 132 lies vertically over the second electrode 182. Thus, the second region 132 is generally an annular area and has a radial width D2.

As indicated in FIG. 2, a wafer 105 lies directly on the surface 139 of the electrostatic chuck 130. A first zone 151 of the wafer 105 lies directly over the first region 131 of the electrostatic chuck 130 and the first electrode 181 in the Z-direction, i.e., the first zone 151 of the wafer 105 lies vertically over the first region 131 of the electrostatic chuck 130 and the first electrode 181. Thus, the first zone 151 is generally disk-shaped and has a diameter D1. A second zone 152 of the wafer 105 lies directly over the second region 132 of the electrostatic chuck 130 and the second electrode 182 in the Z-direction, i.e., the second zone 152 of the wafer 105 lies vertically over the second region 132 of the electrostatic chuck 130 and the second electrode 182. Thus, the second zone 152 is generally annular, such as a rectangular ring, and has a radial width D2. The first zone 151 and second zone 152 are separated by the gap 191 having a radial width G1.

In FIG. 2, the electrostatic chuck 130 is located on a base plate 190. The base plate 190 is made of a material that can withstand the high temperatures, vacuum conditions, and corrosive plasma environment of the plasma process. The electrostatic chuck 130 may be attached to the base plate 190 using a set of bolts or screws, or may be secured to the base plate 190 using a vacuum seal or other mechanism to maintain a vacuum environment during processing. The base plate 190 may be supported by a set of supports or legs that connect the base plate 190 to the plasma processing chamber 110. The supports may be made of a material that can withstand the plasma environment and may be adjustable to allow for precise positioning of the wafer or substrate during processing. It is contemplated that the electrostatic chuck 130 may be removed from the base plate 190 and replaced with an electrostatic chuck 130 having a different arrangement of electrode arrangement 180, such as including a different arrangement of electrodes 181 and 182, or additional electrodes.

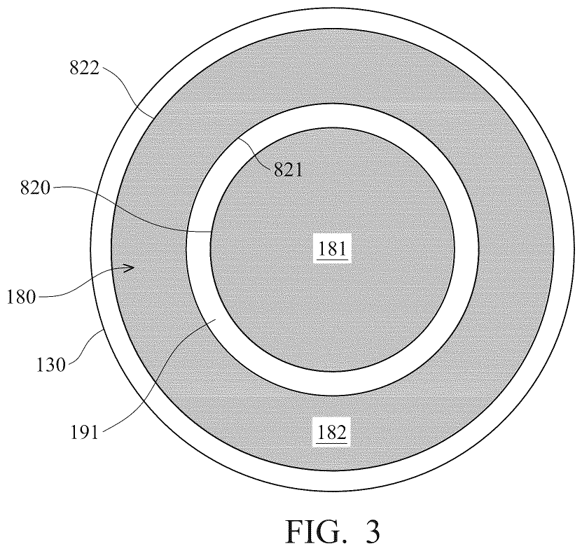

FIG. 3 provides a cross sectional view of the electrostatic chuck of FIG. 2, taken along line 3-3. As shown, the electrode 181 is generally circular and has an outer edge 820. Further, the electrode 182 is generally annular and extends from an inner edge 821 to an outer edge 822. In exemplary embodiments, outer edge 820 is convex cylindrical, inner edge 821 is concave cylindrical, and outer edge 822 is convex cylindrical. Cross-referencing FIGS. 2 and 3, it may be seen that outer edge 820 is distanced from inner edge 821 by gap 191, having a radial width or distance G1. Further, inner edge 821 is distanced from outer edge 822 by radial width D2.

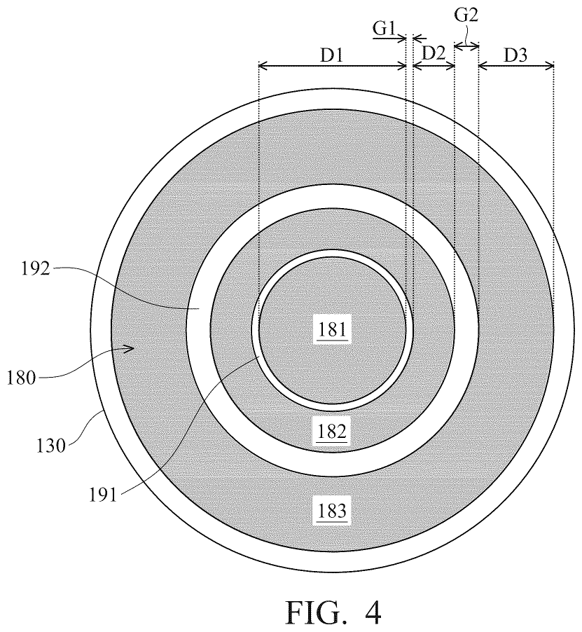

FIG. 4 provides a cross-sectional view, similar to FIG. 3, of another embodiment of an electrode arrangement 180. In FIG. 4, electrode arrangement 180 is provided with three electrodes 181, 182, and 183. Each electrode 181, 182, and 183 is connected to the DC power source 140 (FIG. 2) with a dedicated cable 40 (FIG. 2). Similar to the embodiment of FIG. 3, electrode 181 is located at a central position. Electrode 181 may be generally a disk-shaped sheet and has a diameter D1. As shown, electrode 182 is located radially outward from electrode 181. Electrode 182 may be generally annular shaped sheet and have a radial width or distance D2.

In FIG. 4, electrode arrangement 180 further includes a third electrode 183. Electrode 182 may be generally annular shaped sheet and have a radial width or distance D3.

As shown, electrode 182 is distanced from electrode 181 by an annular gap 191 having a radial distance G1, and electrode 183 is distanced from electrode 182 by an annular gap 192 having a radial distance G2. While gap 191 is illustrated as being smaller than gap 192, gaps 191 and 192 may be independently formed with any desired radial width. Further, it is contemplated that electrode arrangement 180 may be formed with additional annular electrodes and additional annular gaps.

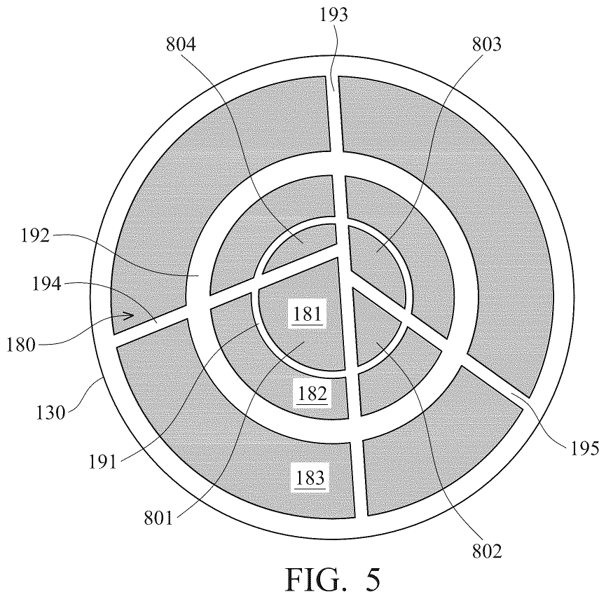

FIG. 5 provides a cross-sectional view, similar to FIG. 3, of another embodiment of an electrode arrangement 180. In FIG. 5, electrode arrangement 180 is provided with three annular electrodes 181, 182, and 183 that are further subdivided into electrode segments. For example, electrode 181 is subdivided into electrode segments 801, 802, 803, and 804. Likewise, electrode 182 is subdivided into four electrode segments, and electrode 183 is subdivided into four electrode segments. Electrode arrangement 180 may be formed by such a pattern by forming annular gaps 191 and 192 and forming linear gaps 193, 194, and 195. While not labeled, each linear gap 193, 194, and 195 may be formed to extend along a directional line and to have a gap width perpendicular to the directional line. Such gap widths may be any suitable distance, such as at least 1 millimeter (mm), at least 2 mm, at least 3 mm, at least 4 mm, at least 5 mm, at least 6 mm, at least 7 mm, at least 8 mm, at least 9 mm, at least 10 mm, at least 15 mm, at least 20 mm, or at least 30 mm; and at most 2 mm, at most 3 mm, at most 4 mm, at most 5 mm, at most 6 mm, at most 7 mm, at most 8 mm, at most 9 mm, at most 10 mm, at most 15 mm, at most 20 mm, or at most 30 mm. In FIG. 5, each electrode segment is connected to the DC power source 140 (FIG. 2) with a dedicated cable 40 (FIG. 2).

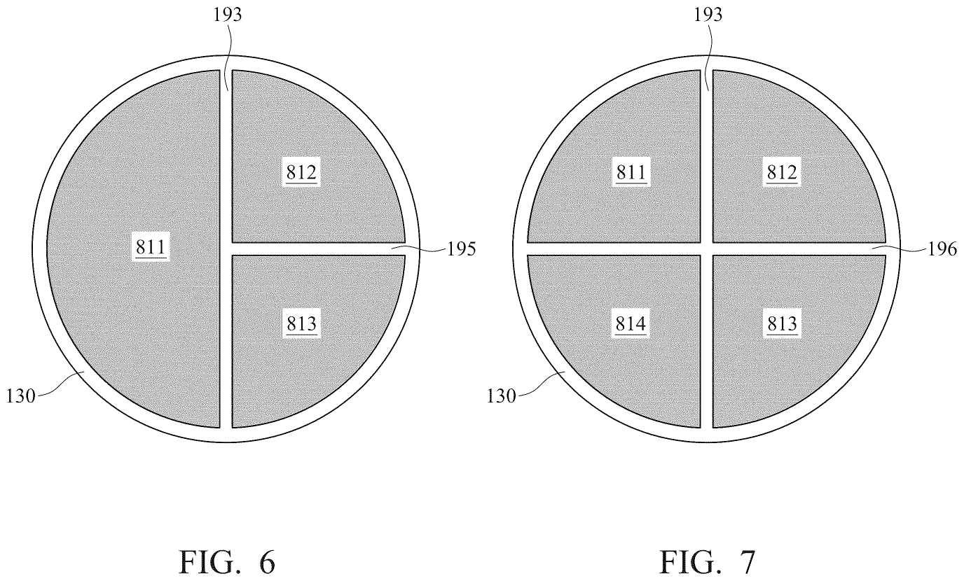

FIG. 6 provides a cross-sectional view, similar to FIG. 3, of another embodiment of an electrode arrangement 180. In FIG. 5, electrode arrangement 180 is provided with three non-annular electrodes 811, 812, and 813, separated by linear gaps 193 and 195 extending along directional lines and having gap widths perpendicular to the respective directional lines. Gap widths may be any desired distance as described above. As shown, electrode 811 generally has a semi-circular cross section, electrode 812 has a quarter-circular cross section, and electrode 813 has a quarter-circular cross section. In embodiments of FIG. 6, each electrode 811, 812, and 813 is connected to the DC power source 140 (FIG. 2) with a dedicated cable 40 (FIG. 2).

FIG. 7 provides a cross-sectional view, similar to FIG. 3, of another embodiment of an electrode arrangement 180. In FIG. 5, electrode arrangement 180 is provided with four non-annular electrodes 811, 812, 813, and 814, separated by linear gaps 193 and 196 extending along directional lines and having gap widths perpendicular to the respective directional lines. Gap widths may be any desired distance as described above. As shown, each electrode 811, 812, 813, and 814 generally has a quarter-circular cross section. In embodiments of FIG. 7, each electrode 811, 812, 813, and 814 is connected to the DC power source 140 (FIG. 2) with a dedicated cable 40 (FIG. 2).

As shown in FIGS. 3-7, the electrode arrangement 180 may be provided with any desired electrode arrangement including electrodes that are distinct from one another such that each electrode may be independently biased. As a result, each region of the surface 139 of the electrostatic chuck 130 and each zone of the wafer 105 lying directly over a respective electrode may be independently biased.

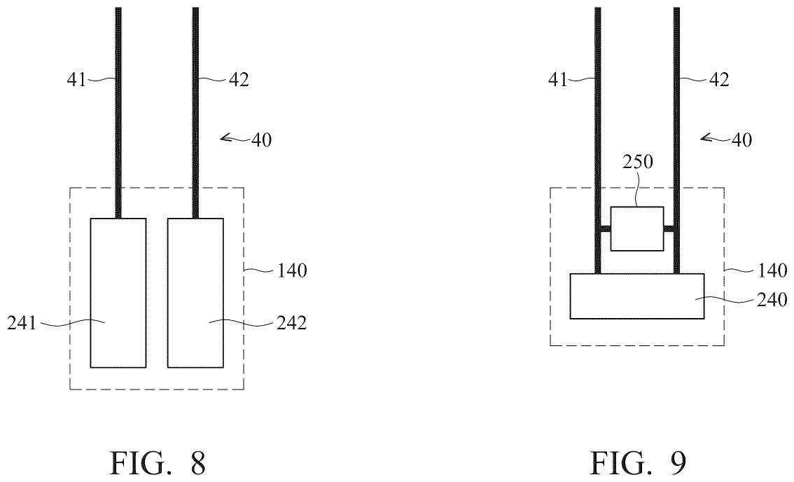

FIGS. 8 and 9 are schematics further illustrating embodiments of the DC power source 140 of FIGS. 1 and 2. Specifically, in FIG. 8 the DC power source 140 includes two distinct power sources 241 and 242. For example, each power source 241 and 242 may independently include a DC generator or power supply, and/or a DC-DC converter. Alternatively, each power source 241 and 242 may independently include an RF generator and an RF-DC converter. Each DC power source 140 may be configured to apply a pulsed bias or DC signal. Therefore, each power source 241 and 242 may include a pulse-width modulation (PWM) controller or other software-controlled system for providing a pulsed signal. The use of a PWM controller or system may allow the pulse duration and repetition rate to be precisely controlled, which can provide greater flexibility and control over the plasma process. Pulsed DC bias may reduce the accumulation of charges on the surface of the wafer during plasma processing. This is because the short, high-voltage pulses are less likely to cause charge buildup than a continuous DC bias. Additionally, pulsed DC bias can be used to create a more uniform plasma density across the wafer surface, which can improve process uniformity and reduce damage to the wafer. Further, each power source 241 and 242 may be used to apply a bias voltage over a wide range of frequencies.

While FIG. 8 illustrates two cables 41 and 42 connected to two power sources 241 and 241 for applying different biases to two electrodes 181 and 182 (FIGS. 1 and 2), it is contemplated that the apparatus 100 (FIG. 1) include a dedicated independent power source 140 for each electrode in electrode arrangement 180. Therefore, if the electrostatic chuck 130 includes eight distinct electrodes in electrode arrangement 180, then the apparatus 100 (FIG. 1) includes eight power sources for independently applying eight biases.

In FIG. 9, the DC power source 240 includes a single power source that is configured to apply two different biases through cables 41 and 42. Specifically, the DC power source 240 includes or is coupled to a resistor-inductor-capacitor (RLC) circuit 250. The RLC circuit 250 is configured to provide a first output with a first bias through cable 41 to electrode 81 (FIGS. 1 and 2) and a second output with a second bias to electrode 82 (FIGS. 1 and 2). An RLC circuit 250 is a type of electronic circuit that consists of a resistor (R), an inductor (L), and a capacitor (C) connected together. The RLC circuit 250 can be used as a bias circuit by adjusting the values of the components. Specifically, by choosing appropriate values of R, L, and C, the circuit can produce two different outputs, each with a different bias. Generally, the first bias output is produced by the voltage drop across the resistor (R) in the circuit. The resistor serves as a voltage divider, which means that it divides the total voltage applied to the circuit into two parts. The voltage drop across the resistor is proportional to the current flowing through the circuit, and it produces a bias voltage that is proportional to the resistance. The second bias output is produced by the voltage across the capacitor (C) in the circuit. The capacitor serves as a charge storage device, and it stores charge when the voltage across it is positive and releases charge when the voltage is negative. This produces a second bias voltage that is proportional to the capacitance. Thus, the RLC circuit 250 provides two different bias outputs by exploiting the properties of the resistor and the capacitor.

While FIG. 9 illustrates two cables 41 and 42 connected to two power sources 241 and 241 for applying different biases to two electrodes 181 and 182 (FIGS. 1 and 2), it is contemplated that the apparatus 100 (FIG. 1) include a dedicated power source 140 for pairs of electrodes in electrode arrangement 180. Therefore, if the electrostatic chuck 130 includes eight distinct electrodes in electrode arrangement 180, then the apparatus 100 (FIG. 1) includes four power sources and four RLC circuits 250 capable of applying eight different biases.

In view of the above, it is understood that each surface region of the electrostatic chuck and corresponding zone of wafer may be independently biased with a desired DC signal. Each desired DC signal may be a pulsed signal or have any desired waveform. Each desired DC signal may be a waveform generated in any selected frequency. Each desired DC signal may have a different sheath waveform. Each desired DC signal may be dynamically selected and applied by a controller or software, such as controller 60 (FIG. 1).

Further, each desired DC signal may be provided with an independently selected voltage, independently selected phase, and independently selected power. Further, the high state and low state of bias can be an arbitrary time combination for each desired DC signal.

In an example, a chuck electrode arrangement 180 is provided with four electrodes defining four zones on the wafer. In the example, a first bias/DC signal is applied to a first zone with a 0 degree phase, at a voltage of 100 volts, and with a power of 50 watts; a second bias/DC signal is applied to a second zone with a 90 degree phase, at a voltage of 150 volts, and with a power of 70 watts; a third bias/DC signal is applied to a third zone with a 90 degree phase, at a voltage of 130 volts, and with a power of 90 watts; and a fourth bias/DC signal is applied to a fourth zone with a 180 degree phase, at a voltage of 100 volts, and with a power of 60 watts. Such an example is merely provided for further understanding the ability to provide four different biases and is not intended to be limiting.

It is noted that embodiment herein do not require a matching box for applying the bias voltage to the electrodes in the electrode arrangement 180.

In some embodiments, the apparatus and components of FIGS. 1-9 are configured to hold and process a wafer 105 having a diameter of 100 mm, 150 mm, 200 mm, or 300 mm, or other desired diameter.

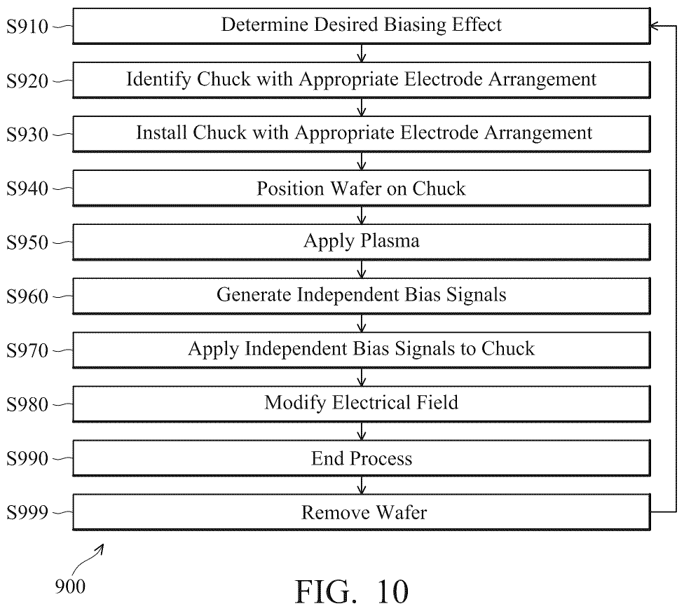

Referring now to FIG. 10, a method 900 for plasma processing is described. As shown, method 900 includes, at S910, determining a desired biasing effect on the wafer, such as at different zones of the wafer.

Further, method 900 may include, at S920, identifying an electrostatic chuck having an electrode arrangement capable of providing the desired biasing effect. For example, S920 may include designing and forming, or selecting, an electrostatic chuck having an electrode arrangement capable of providing the desired biasing effect.

Method 900 may continue at S930 with installing the identified electrostatic chuck having the appropriate electrode arrangement on the base plate in the plasma chamber.

Further, method 900 includes positioning a workpiece, such as a wafer, on the electrostatic chuck at S940. As a result, the electrostatic chuck supports the wafer. The wafer may be secured in place by the electrostatic chuck.

At S950, the plasma process is initiated by applying a plasma. For example, the plasma may be ignited in the chamber and over the workpiece. In some embodiments, the apparatus is operated to introduce the desired etchants into the chamber 110 and to ignite them into the plasma 125 through application of RF power. The source of RF power 120 may be configured to generate an RF signal operating at a set frequency (e.g., 13.56 MHZ), which transfers energy from the source of RF power 120 to the etchant gas within the processing chamber 110. When sufficient power has been delivered to the gas, a plasma is ignited. In some embodiments, the power applied during the etching operations ranges from about 200 watts to about 700 watts. In some embodiments, application of an RF pulse occurs for a duration of about 10 seconds to about 60 seconds.

At S960, method 900 includes generated independent bias signals as described above. For example, a first DC bias signal and a second DC bias signal may be generated.

Further, at S970, the method 900 includes applying the desired bias to the chuck. Specifically, each electrode may be independently biased as described above. For example, a first region of the chuck may be biased with the first DC bias signal and a second region of the chuck may be biased with the second DC bias signal different from the first DC bias signal. It is contemplated that S950 and S970 may be commenced in either order or simultaneously.

As a result of applying the desired bias to the chuck, at S980 method 900 modifies the electrical field around the wafer.

Thus, S960-S980 directs a direction of ion flow by applying a first DC bias signal to a first region of the electrostatic chuck and applying a second DC bias signal to a second region of the electrostatic chuck. In exemplary embodiments, a first pulsed direct current (DC) signal is applied to the first region of the electrostatic chuck and a second pulsed direct current (DC) signal is applied to the second region of the electrostatic chuck.

Method 900 may continue at S990 with ending the plasma process. Then, at S999, the wafer may be removed from the chamber.

It is noted that further processing may be performed by repeating the method 900, beginning at S910. If a different biasing effect is desired, then the method removes the current chuck and replaces it with a new chuck having a different electrode arrangement at S930.

Thus, one of the embodiments of the present disclosure describes a processing apparatus including an electrostatic chuck configured to hold a semiconductor wafer during a process performed on the semiconductor wafer; a first electrode configured to bias a first region of the electrostatic chuck with a first bias; and a second electrode configured to bias a second region of the electrostatic chuck with a second bias.

In some embodiments, the apparatus further includes a first direct current (DC) power source coupled to the first electrode; and a second direct current (DC) power source coupled to the second electrode.

In some embodiments, the apparatus further includes a direct current (DC) power source; and a resistor-inductor-capacitor (RLC) circuit coupled to the DC power source and configured to provide a first output with a first bias to the first electrode and a second output with a second bias to the second electrode.

In some embodiments of the apparatus, a gap is defined between the first electrode and the second electrode, wherein the gap is annular.

In some embodiments of the apparatus, a gap is defined between the first electrode and the second electrode, wherein the gap is linear.

In some embodiments, the apparatus further includes a controller configured to change the first bias and the second bias during the process. In some embodiments of the apparatus, the controller is configured to provide the first bias and second bias with a different phase, voltage, and/or power.

In some embodiments of the apparatus, the process is an electron cyclotron resonance (ECR) process, a capacitively coupled plasma (CCP) process, an inductively coupled plasma (ICP) process, a plasma vaper deposition (PVD) or sputter deposition process.

In some embodiments, the apparatus further includes a third electrode configured to bias a third region of the electrostatic chuck with a third bias.

Another embodiment of the present disclosure describes a plasma processing apparatus including a plasma chamber configured to receive a semiconductor wafer for a plasma process; and an electrostatic chuck disposed in the chamber, wherein the electrostatic chuck has an upper surface configured to support a semiconductor wafer during the plasma process, wherein the upper surface includes a first region configured to apply a first bias to the semiconductor wafer, and wherein the upper surface includes a second region configured to apply a second bias to the semiconductor wafer.

In some embodiments, the apparatus further includes a first direct current (DC) power source for generating the first bias; and a second direct current (DC) power source for generating the second bias.

In some embodiments, the apparatus further includes a direct current (DC) power source for generating a bias; and a resistor-inductor-capacitor (RLC) circuit coupled to the DC power source and configured to provide the first bias to the first region and the second bias to the second region.

In some embodiments of the apparatus, a surface gap is defined on the upper surface between the first region and the second region, wherein the surface gap is annular.

In some embodiments of the apparatus, a surface gap is defined on the upper surface between the first region and the second region, wherein the surface gap is linear.

In some embodiments, the apparatus further includes a controller configured to change the first bias and the second bias during the plasma process.

Another embodiment of the present disclosure describes a method for plasma processing including supporting a workpiece with an electrostatic chuck; igniting a plasma over the workpiece; and directing a direction of ion flow by applying a first bias to a first region of the electrostatic chuck and applying a second bias to a second region of the electrostatic chuck.

In some embodiments of the method, applying the first bias to the first region of the electrostatic chuck and applying the second bias to the second region of the electrostatic chuck includes applying a first pulsed direct current (DC) signal to the first region of the electrostatic chuck and applying a second pulsed direct current (DC) signal to the second region of the electrostatic chuck.

In some embodiments, the method further includes generating a first direct current (DC) signal with a first direct current (DC) power source; and generating a second direct current (DC) signal with a second direct current (DC) power source.

In some embodiments, the method further includes generating a direct current (DC) signal with a direct current (DC) power source; and converting the DC signal into a first output with the first bias and a second output with the second bias with a resistor-inductor-capacitor (RLC) circuit.

In some embodiments of the method, the electrostatic chuck is a first electrostatic chuck and includes a first electrode defining the first region and a second electrode defining the second region in a first arrangement, and the method further includes replacing the first electrostatic chuck with a second electrostatic chuck including a second arrangement of a first electrode and a second electrode; supporting a second workpiece with the second electrostatic chuck; igniting a plasma over the second workpiece; and directing a direction of ion flow by applying a first bias to the first region of the electrostatic chuck and applying a second bias to the second region of the second electrostatic chuck.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present.

What is claimed is:

1. A processing apparatus comprising:
an electrostatic chuck configured to hold a semiconductor wafer during a process performed on the semiconductor wafer;
a first electrode configured to bias a first region of the electrostatic chuck with a first bias; and
a second electrode configured to bias a second region of the electrostatic chuck with a second bias.

2. The processing apparatus of claim 1, further comprising:
a first direct current (DC) power source coupled to the first electrode; and
a second direct current (DC) power source coupled to the second electrode.

3. The processing apparatus of claim 1, further comprising:
a direct current (DC) power source; and
a resistor-inductor-capacitor (RLC) circuit coupled to the DC power source and configured to provide a first output with a first bias to the first electrode and a second output with a second bias to the second electrode.

4. The processing apparatus of claim 1, wherein a gap is defined between the first electrode and the second electrode, wherein the gap is annular.

5. The processing apparatus of claim 1, wherein a gap is defined between the first electrode and the second electrode, wherein the gap is linear.

6. The processing apparatus of claim 1, further comprising a controller configured to change the first bias and the second bias during the process.

7. The processing apparatus of claim 6, wherein the controller is configured to provide the first bias and second bias with a different phase, voltage, and/or power.

8. The processing apparatus of claim 1, wherein the process is an electron cyclotron resonance (ECR) process, a capacitively coupled plasma (CCP) process, an inductively coupled plasma (ICP) process, a plasma vaper deposition (PVD) or sputter deposition process.

9. The processing apparatus of claim 1, further comprising a third electrode configured to bias a third region of the electrostatic chuck with a third bias.

10. A plasma processing apparatus comprising:
a plasma chamber configured to receive a semiconductor wafer for a plasma process; and
an electrostatic chuck disposed in the plasma chamber, wherein the electrostatic chuck has an upper surface configured to support the semiconductor wafer during the plasma process, wherein the upper surface includes a first region configured to apply a first bias to the semiconductor wafer, and wherein the upper surface includes a second region configured to apply a second bias to the semiconductor wafer.

11. The plasma processing apparatus of claim 10, further comprising:
a first direct current (DC) power source for generating the first bias; and
a second direct current (DC) power source for generating the second bias.

12. The plasma processing apparatus of claim 10, further comprising:
a direct current (DC) power source for generating a bias; and
a resistor-inductor-capacitor (RLC) circuit coupled to the DC power source and configured to provide the first bias to the first region and the second bias to the second region.

13. The plasma processing apparatus of claim 10, wherein a surface gap is defined on the upper surface between the first region and the second region, wherein the surface gap is annular.

14. The plasma processing apparatus of claim 10, wherein a surface gap is defined on the upper surface between the first region and the second region, wherein the surface gap is linear.

15. The plasma processing apparatus of claim 10, further comprising a controller configured to change the first bias and the second bias during the plasma process.

16. A method for plasma processing comprising:
supporting a workpiece with an electrostatic chuck;
igniting a plasma over the workpiece; and
directing a direction of ion flow by applying a first bias to a first region of the electrostatic chuck and applying a second bias to a second region of the electrostatic chuck.

17. The method of claim 16, wherein applying the first bias to the first region of the electrostatic chuck and applying the second bias to the second region of the electrostatic chuck comprises applying a first pulsed direct current (DC) signal to the first region of the electrostatic chuck and applying a second pulsed direct current (DC) signal to the second region of the electrostatic chuck.

18. The method of claim 16, further comprising:
generating a first direct current (DC) signal with a first direct current (DC) power source; and
generating a second direct current (DC) signal with a second direct current (DC) power source.

19. The method of claim 16, further comprising:
generating a direct current (DC) signal with a direct current (DC) power source; and
converting the DC signal into a first output with the first bias and a second output with the second bias with a resistor-inductor-capacitor (RLC) circuit.

20. The method of claim 16, wherein the electrostatic chuck is a first electrostatic chuck and includes a first electrode defining the first region and a second electrode defining the second region in a first arrangement, and wherein the method further comprises:
replacing the first electrostatic chuck with a second electrostatic chuck including a second arrangement of a first electrode and a second electrode;
supporting a second workpiece with the second electrostatic chuck;
igniting a plasma over the second workpiece; and
directing a direction of ion flow by applying a first bias to the first region of the electrostatic chuck and applying a second bias to the second region of the second electrostatic chuck.
